(19) United States
(12) Patent Application Publication
(10) Pub. No.: US 2024/0224421 A1
(43) Pub. Date: Jul. 4, 2024

(54) WIRING BOARD UNIT AND METHOD FOR DESIGNING THE SAME

(71) Applicant: TOPPAN HOLDINGS INC., Tokyo (JP)

(72) Inventors: Ryoma TANABE, Tokyo (JP); Masahito Tanabe, Tokyo (JP); Fusao Takagi, Tokyo (JP)

(73) Assignee: TOPPAN HOLDINGS INC., Tokyo (JP)

(21) Appl. No.: 18/610,636

(22) Filed: Mar. 20, 2024

Related U.S. Application Data
(63) Continuation of application No. PCT/JP2022/033438, filed on Sep. 6, 2022.

(30) Foreign Application Priority Data
Sep. 22, 2021 (JP) 2021-153737
Sep. 22, 2021 (JP) 2021-153745
Aug. 30, 2022 (JP) 2022-136522
Aug. 30, 2022 (JP) 2022-136524

(51) Int. Cl. H05K 1/05; H01L 23/14; H01L 23/32; H05K 3/46

(52) U.S. Cl. CPC H05K 1/056; H01L 23/142; H01L 23/32; H05K 3/4626

(57) ABSTRACT

A wiring board unit capable of reducing the stress inside the wiring board to reduce the risk of a crack being formed from a location where stress is concentrated. To achieve this, the present invention includes a first wiring board and a second wiring board bonded to the first wiring board. A semiconductor element being resin-sealed on a surface side of the second wiring board opposite to a surface for bonding with the first wiring board. A tensile strength of an insulating resin material used for the second wiring board and a width of a Cu pattern formed on the side opposite to the first wiring board give a value smaller than 0.5 when substituted in Formula 1 below.

$$\begin{matrix}1 / ( 1 + Exp ( - A ) ) \\ A = - 15 \text{.45} - 0.1654 \times Tensile strength + 11.31 \times log ( Cu pattern width )\end{matrix} \qquad ( 1 )$$

### CROSS-REFERENCE TO RELATED PATENT APPLICATIONS

This application is a continuation application filed under 35 U.S.C. § 111(a) claiming the benefit under 35 U.S.C. §§ 120 and 365(c) of International Patent Application No. PCT/JP2022/033438, filed on Sep. 6, 2022, which is based upon and claims the benefit to Japanese Patent Application Nos. 2021-153737, and 2021-153745, both filed on Sep. 22, 2021; and Japanese Patent Application Nos. 2022-136522, and 2022-136524, both filed on Aug. 30, 2022, the disclosures of which are incorporated herein by reference in their entirety.

### TECHNICAL FIELD

The present invention relates to a wiring board and a method for designing the same.

### BACKGROUND

When mounting semiconductor elements having fine wiring circuits on motherboards, the spacing between and size of electrodes serving as junction terminals of the semiconductor element do not necessarily match those of the motherboard. To address this, an intermediate substrate called a flip chip-ball grid array (FC-BGA) substrate is generally used between the semiconductor element and the motherboard. Such an intermediate substrate makes it possible to establish connection by converting the spacing between and size of the electrodes.

However, due to the increasing demand for faster and more highly integrated semiconductor devices, the FC-BGA substrates on which semiconductor elements are mounted are also required to have junction terminals with a narrower pitch and finer wiring.

On the other hand, for the spacing between the junction terminals between the FC-BGA substrate and the motherboard, they are required to have a pitch that is almost the same as the conventional pitch.

In order to cope with the narrowing of the pitch of the junction terminals of semiconductor elements and the accompanying miniaturization of the wiring in FC-BGA substrates, a multilayer wiring board having fine wiring is used between the FC-BGA substrate and the semiconductor element as an additional intermediate substrate also called an interposer.

Techniques for mounting a plurality of semiconductor elements on an FC-BGA substrate via such an interposer have emerged.

Early interposers were manufactured using a technique in the semiconductor element manufacturing process corresponding to a silicon wafer processing technique. However, when the semiconductor element manufacturing process is used, there is a problem that the manufacturing cost increases. In addition, regarding the interposers produced using silicon wafers, problems with their transmission characteristics due to the electrical characteristics of silicon itself have been pointed out.

There is also a method for forming a multilayer wiring board having a narrow pitch on the FC-BGA substrate by forming the interposer with a support such as a glass substrate and removing the substrate after mounting this on the FC-BGA substrate (PTL 1).

However, glass interposers have a problem in the processability of glass.

As a technique to compensate for the defects glass interposers have, there is a technique of forming an interposer using an organic insulating resin.

In the case where an interposer formed using an organic insulating resin is used, the wiring board is formed using an organic insulating resin and a wiring material on a support called a carrier. After mounting semiconductor elements on the wiring board and sealing it with resin, the support is removed, and the sealed wiring board is attached to the FC-BGA substrate to form a semiconductor device (PTL 2).

[Citation List] [Patent Literature] [PTL 1] WO 2018/047861; [PTL 2] US 2021/0050298 A.

### SUMMARY OF THE INVENTION

### Technical Problem

However, when an interposer is formed using an organic insulating resin, thermal changes may cause the conduction layer of the wiring board to peel off or the organic insulating resin to crack because the organic insulating resin has a larger coefficient of thermal expansion (CTE) than the FC-BGA.

In other words, if the surrounding temperature changes significantly after the interposer is attached to the FC-BGA, only the organic insulating resin in the wiring board deforms significantly, causing the wiring board to warp or generating stress inside the wiring board. Consequently, fine wiring layers or other layers may be peeled, or cracking may occur, originating from the areas of peeling or the areas where stresses are concentrated.

The present invention has been made in light of the issues set forth above and aims to provide a wiring board unit which relieves stresses inside the wiring board and is less likely to cause cracking originating from areas where stresses are concentrated.

### Solution to Problem

In order to solve the aforementioned problems, one typical wiring board unit according to the present invention includes a first wiring board and a second wiring board bonded to the first wiring board. A semiconductor element being resin-sealed on a surface side (hereinafter referred to as “first surface”) of the second wiring board opposite to a surface for bonding with the first wiring board.

A tensile strength of an insulating resin material used for the second wiring board and a width of a Cu pattern formed on the first wiring board give a value smaller than 0.5 when substituted in Formula 1 below.

$$\begin{matrix}[ Formula 1 ] & \\ \begin{matrix}1 / ( 1 + Exp ( - A ) ) \\ A = - 15 \text{.45} - 0.1654 \times Tensile strength + 11.31 \times log ( Cu pattern width )\end{matrix} & ( 1 )\end{matrix}$$

Further, in order to solve the aforementioned problems, one typical wiring board unit according to the present invention includes a first wiring board and a second wiring board bonded to the first wiring board. A semiconductor element can be implemented on a surface side (hereinafter referred to as “first surface”) of the second wiring board opposite to a surface for bonding with the first wiring board.

A tensile strength of an insulating resin material used for the second wiring board and a width of a Cu pattern formed on the first wiring board give a value smaller than 0.5 when substituted in Formula 2 below.

$$\begin{matrix}[ Formula 2 ] & \\ \begin{matrix}1 / ( 1 + Exp ( - A ) ) \\ A = 0.227 - 0.1619 \times Tensile strength + 6.648 \times log ( Cu pattern width )\end{matrix} & ( 2 )\end{matrix}$$

### Advantageous Effects of the Invention

According to the present invention, it is possible to provide a wiring board unit capable of easing the stress inside the wiring board to reduce the risk of cracking occurring from locations where stress is concentrated.

Issues, configurations, and effects other than those described above will be clarified in the following description on modes for carrying out the invention.

### BRIEF DESCRIPTION OF THE DRAWINGS

FIG. 1 is a cross-sectional view illustrating a release layer formed on a support.

FIG. 2A is a cross-sectional view illustrating a state in which a photosensitive resin layer is formed.

FIG. 2B is a cross-sectional view illustrating a state in which a seed adhesion layer is formed.

FIG. 2C is a cross-sectional view illustrating a state in which a seed layer is formed.

FIG. 2D is a cross-sectional view illustrating a state in which a conduction layer is formed.

FIG. 2E is a cross-sectional view illustrating a state in which a conduction layer and the seed layer have been polished by surface polishing.

FIG. 2F is a cross-sectional view illustrating a state in which the seed adhesion layer and the photosensitive resin layer have been polished by surface polishing to form electrodes for bonding to semiconductor elements.

FIG. 3A is a cross-sectional view illustrating a state in which a photosensitive resin layer for via parts is formed.

FIG. 3B is a cross-sectional view illustrating a state in which a photosensitive resin layer for the via parts and wiring parts is formed.

FIG. 3C is a cross-sectional view illustrating a state in which a seed adhesion layer is formed.

FIG. 3D is a cross-sectional view illustrating a state in which a seed layer is formed.

FIG. 3E is a cross-sectional view illustrating a state in which a conduction layer is formed.

FIG. 3F is a cross-sectional view illustrating a state in which the via parts and wiring parts are formed by surface polishing.

FIG. 4A is a cross-sectional view illustrating a state in which multilayer wiring is formed by repeating FIGS. 3A to 3F.

FIG. 4B is a cross-sectional view illustrating a state in which the multilayer wiring is formed by SAP.

FIG. 4C is a cross-sectional view illustrating a state in which Cu pillars are formed on the multilayer wiring.

FIG. 5A is a cross-sectional view illustrating a state in which the multilayer wiring on the support and the semiconductor elements have been bonded.

FIG. 5B is a cross-sectional view illustrating a state in which underfill is formed.

FIG. 5C is a cross-sectional view illustrating a state in which a sealing resin is formed.

FIG. 5D is a cross-sectional view illustrating a state in which the release layer is irradiated with laser light.

FIG. 5E is a cross-sectional view illustrating the removed support and the separated multilayer wiring.

FIG. 5F is a cross-sectional view of a wiring board unit in which the multilayer wiring and a FC-BGA substrate are bonded.

FIG. 6 is an enlarged detailed cross-sectional view of an enclosed region A-A′ in FIG. 5F.

FIG. 7 is a graph of Formula 1.

FIG. 8 is a cross-sectional view illustrating a state in which a photosensitive resin layer is formed on an intermediate layer in a second manufacturing method of the first embodiment.

FIG. 9A is a cross-sectional view illustrating a state in which the multilayer wiring on the support and the semiconductor elements have been bonded in the second manufacturing method.

FIG. 9B is a cross-sectional view illustrating a state in which underfill is formed in the second manufacturing method.

FIG. 9C is a cross-sectional view illustrating a state in which a sealing resin is formed in the second manufacturing method.

FIG. 9D is a cross-sectional view illustrating a state in which the release layer is irradiated with laser light in the second manufacturing method.

FIG. 9E is a cross-sectional view illustrating the removed support and the separated multilayer wiring in the second manufacturing method.

FIG. 10A is a cross-sectional view illustrating a state in which a photosensitive resin layer is formed.

FIG. 10B is a cross-sectional view illustrating a state in which a seed adhesion layer is formed.

FIG. 10C is a cross-sectional view illustrating a state in which a seed layer is formed.

FIG. 10D is a cross-sectional view illustrating a state in which a resist pattern is formed.

FIG. 10E is a cross-sectional view illustrating a state in which a conduction layer is formed.

FIG. 10F is a cross-sectional view illustrating a state in which a resist pattern is removed.

FIG. 10G is a cross-sectional view illustrating a state in which the unnecessary parts of the seed adhesion layer and seed layer have been etched and removed.

FIG. 11A is a cross-sectional view illustrating a state in which a solder resin layer is formed.

FIG. 11B is a cross-sectional view illustrating a state in which a surface-treatment layer and solder bonding parts are formed and thus the wiring board on the support is completed.

FIG. 12A is a cross-sectional view illustrating a state in which the wiring board on the support and the FC-BGA substrate have been bonded and sealed with an underfill layer.

FIG. 12B is a cross-sectional view illustrating a state in which the release layer is irradiated with laser light.

FIG. 12C is a cross-sectional view illustrating the removed support and the separated wiring board unit.

FIG. 13 is an enlarged detailed cross-sectional view of an enclosed region A-A′ in FIG. 12C.

FIG. 14 is a graph of Formula 2.

FIG. 15 is a view illustrating a state in which a photosensitive resin layer is formed on an intermediate layer in the second manufacturing method of the second embodiment.

### DETAILED DESCRIPTION

Embodiments of the present invention will be described below with reference to the drawings. In the following description of the drawings, components identical with or similar to each other are given the same or similar reference signs. It should be noted that the drawings are only schematically illustrated, and thus the relationship between thickness and planar dimensions of the components, the thickness ratio between the layers, and the like are not to scale. Accordingly, the specific thickness and dimensions should be understood referring to the following description. As a matter of course, dimensional relationships or ratios may be different between the drawings.

The embodiment described below only exemplifies a device or a method embodying the technical idea of the present invention. The technical idea of the present invention should not limit the materials, shapes, structures, layouts, and the like of the components to those described below. The technical idea of the present invention can be variously modified within the technical scope defined in the claims.

Note that in the present disclosure, the term “surface” may refer to not only a surface of a plate-shaped member, but also an interface of a layer included in a plate-shaped member and substantially parallel to a surface of the plate-shaped member. The terms “upper surface” and “lower surface” refer to surfaces illustrated in upper and lower areas of a drawing when a plate-shaped member, a layer included in a plate-shaped member, or the like is illustrated in the drawings. The terms “upper surface” and “lower surface” may also be referred to as a “first surface” and a “second surface”.

The term “side surface” refers to a thickness portion of a plate-like member, or a thickness portion of a surface or a layer included in the plate-like member. Furthermore, part of a surface and a side surface may be collectively referred to as “end portion”.

The term “above” refers to the vertically upward direction when a plate-like member or a layer is horizontally placed. Further, the term “above” and the term “below” that is opposite to the “above” may be referred to as a “positive Z-axis direction” and “negative Z-axis direction”. The horizontal direction may also be referred to as an “X-axis direction” or a “Y-axis direction”.

The term “planar shape” or “in plan view” refers to a shape when a surface or a layer is seen from above. The term “cross-sectional shape” or “as viewed in cross section” refers to a shape as seen in a horizontal direction when a plate-like member or a layer is sectioned in a specific direction.

### First Embodiment

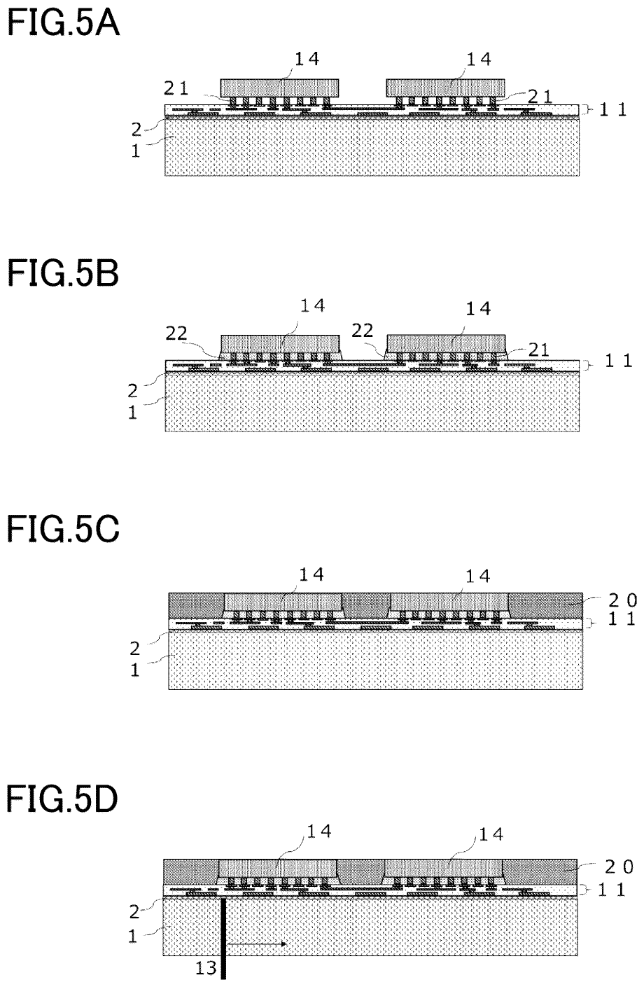

First, with reference to FIG. 5F, the first embodiment of the present disclosure will be described.

FIG. 5F is a cross-sectional view of the wiring board unit 15 in which the multilayer wiring 11 and the FC-BGA substrate 12 are bonded.

The wiring board unit 15 includes a first wiring board including the FC-BGA substrate 12 and a second wiring board including the multilayer wiring 11 and manufactured separately from the first wiring board. Semiconductor elements 14 are fixed to one surface of the second wiring board with underfill 22. The second wiring board and the semiconductor elements are resin-sealed to the first wiring board.

Further, as shown in FIG. 5F, one surface of the multilayer wiring 11 is connected to the FC-BGA substrate 12. The other surface (hereinafter referred to as “first surface”) opposite to that bonding surface is bonded to the semiconductor elements 14.

In FIG. 5F, bonding parts between the semiconductor elements 14 and the multilayer wiring 11 are denoted by 21, and bonding parts between the multilayer wiring 11 and the FC-BGA substrate 12 are denoted by 23.

The inventors predicted that peeling of the fine wiring layer and cracking from a location that has peeled off or a location where stress is concentrated that occur in wiring board units like the one described above are linked with the relative relationship between the width of the Cu pattern formed on the first surface, which is the uppermost layer of the second wiring board, and the tensile strength of the insulating resin material of the second wiring board, and studied this relationship.

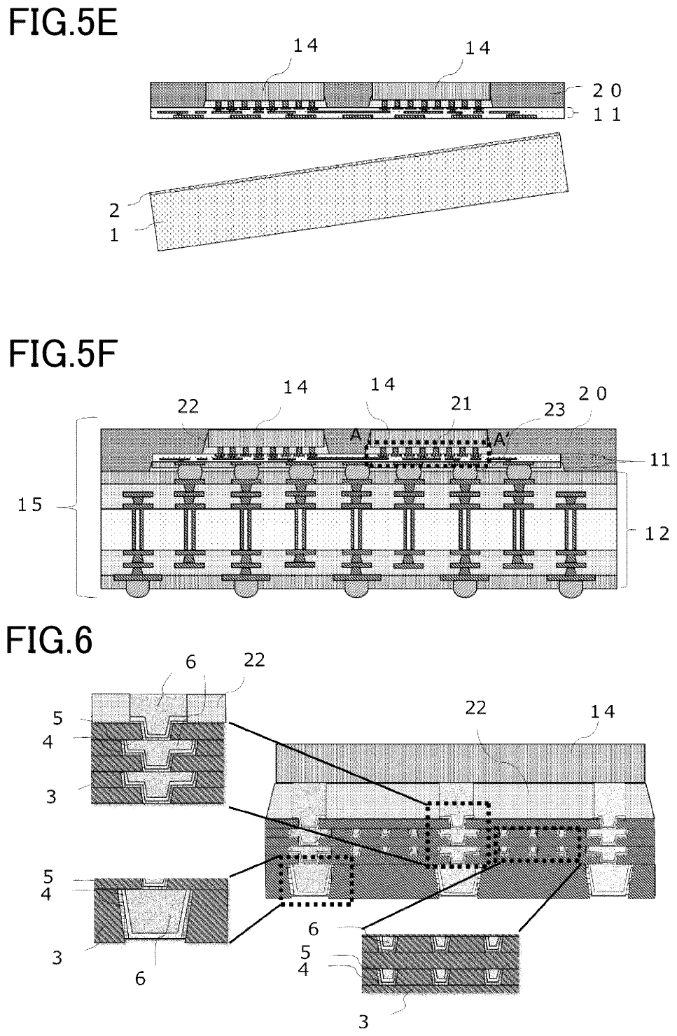

The contents will be explained below with reference to FIG. 6, Tables 1 and 2, Formula 1, and the like.

FIG. 6 is an enlarged detailed cross-sectional view of an enclosed region A-A′ in FIG. 5F. In FIG. 6, five kinds of wiring board units 15 in which the uppermost conduction layers 6 of the second wiring boards have Cu patterns with different widths, specifically, 20, 50, 100, 1000, and 2000 μm were prepared. In addition, five kinds of resins having different tensile strengths, specifically, 90, 135, 145, and 170 (two kinds) MPa were used. Two kinds of resins having a tensile strength of 170 MPa but whose other physical properties differ were used to observe the influence of physical properties other than tensile strength.

A temperature cycle test was conducted on the samples thus manufactured under the following conditions to see if cracking occurred.
Test type: TST
Standard: JESD22-A106B (Condition D)
Temperature: A temperature cycle from (1) to (2), from (2) to (3), from (3) to (2), and from (2) to (1) was implemented where (1) represents 150° C./5 min, (2) represents room temperature/1 min, and (3) represents −65° C./5 min.
Number of cycles: 1000
The number of evaluations was N=4. Table 1 shows the results.

TABLE 1

| | |
|---|---|
| (Resin type) | Probability of cracking % |

| | | | | | | |
|---|---|---|---|---|---|---|
| Tensile | 170 | (A) | 0 | 0 | 0 | 0 |
| strength | 170 | (B) | 0 | 0 | 0 | 0 |
| MPa | 145 | (C) | 0 | 0 | 0 | 25 |
| | 135 | (D) | 0 | 0 | 0 | 25 |
| | 90 | (E) | 0 | 0 | 100 | 100 |

| | | | | |
|---|---|---|---|---|
| TST 1000 Cy | 20 | 100 | 1000 | 2000 |

Cu width μm

In order to determine the occurrence of cracking, nominal logistic regression was performed using the results shown in Table 1 to estimate a binary value indicating if cracking occurs or not, thereby obtaining the following Formula 1.

$$\begin{matrix}[ Formula 1 ] & \\ \begin{matrix}1 / ( 1 + Exp ( - A ) ) \\ A = - 15 \text{.45} - 0.1654 \times Tensile strength + 11.31 \times log ( Cu pattern width )\end{matrix} & ( 1 )\end{matrix}$$

Table 2 shows the values of Formula 1 calculated using the tensile strength of the resin of the fine wiring layer and the Cu pattern width of each substrate.

TABLE 2

| | (Resin type) | Result of Formula 1 | | | |
|---|---|---|---|---|---|
| Tensile | 170 | 3E−13 | 8E−10 | 7E−05 | 0.0020 |
| strength | 170 | 3E−13 | 8E−10 | 7E−05 | 0.0020 |
| MPa | 145 | 2E−11 | 5E−08 | 0.0041 | 0.1093 |
| | 135 | 1E−10 | 3E−07 | 0.0209 | 0.3907 |
| | 90 € | 2E−07 | 0.0004 | 0.9732 | 0.9991 |

| | | | | |
|---|---|---|---|---|
| TST 1000 Cy | 20 | 100 | 1000 | 2000 |

Cu width μm

In Table 2 above, for example, “3E-13” and the like represent exponential notation, and means “3×10⁻¹³”.

The values in Table 2 obtained from Formula 1 are expressed in the range of 0 to 1, with 0 indicating that cracking does not occur and 1 indicating that cracking occurs. That is, a value in Table 2 can be replaced with the probability of cracking by multiplying the value by 100.

According to Tables 1 and 2, no cracks were observed after 1000 TST cycles in the substrates with a tensile strength and a Cu pattern width that give a value of 0.1 or smaller in Table 2. As for substrates with a tensile strength and a Cu pattern width that give a value of 0.1 or greater when substituted in Formula 1, in more than half of the substrates, resin cracking occurred in the fine wiring layer after 1000 TST cycles. This indicates that the probability of cracking obtained from Formula 1 is appropriate.

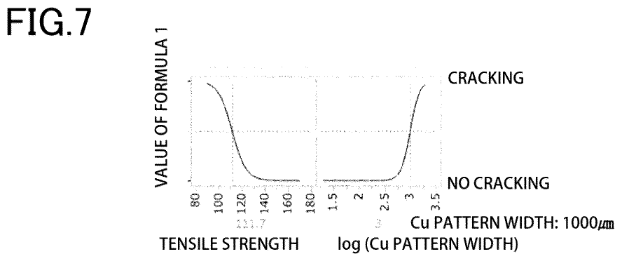

FIG. 7 shows a graph of Formula 1. In FIG. 7, the lateral broken line indicates the position where the value of Formula 1 is 0.5. In other words, this indicates the critical point between when cracking occurs and when cracking does not occur. By finding the intersection of the conditions that give a value of 0.5 when substituted in Formula 1 and the graph of Formula 1, a Cu pattern width of 1000 μm and a resin tensile strength of 111.7 can be obtained. This means that when the Cu pattern width is 1000 μm, it is necessary to use a resin with a tensile strength of 111.7 MPa or higher.

Therefore, it can be seen that the probability of cracking in the resin of the fine wiring layer has a critical point at the point where the value of Formula 1 is 0.5, and selecting a resin with a tensile strength according to the design value of the Cu pattern width is effective in ensuring that the resin in the fine wiring layer is resistant to cracking.

Further, the probability of cracking or the like is preferably less than 0.5, and preferably 0.1 or less. In this case, the required conditions for the wiring board unit can be determined by finding the relationship between the resin tensile strength of and the Cu pattern width that gives a value of 0.1 or less when substituted in Formula 1.

### <First Method of Manufacturing First Embodiment>

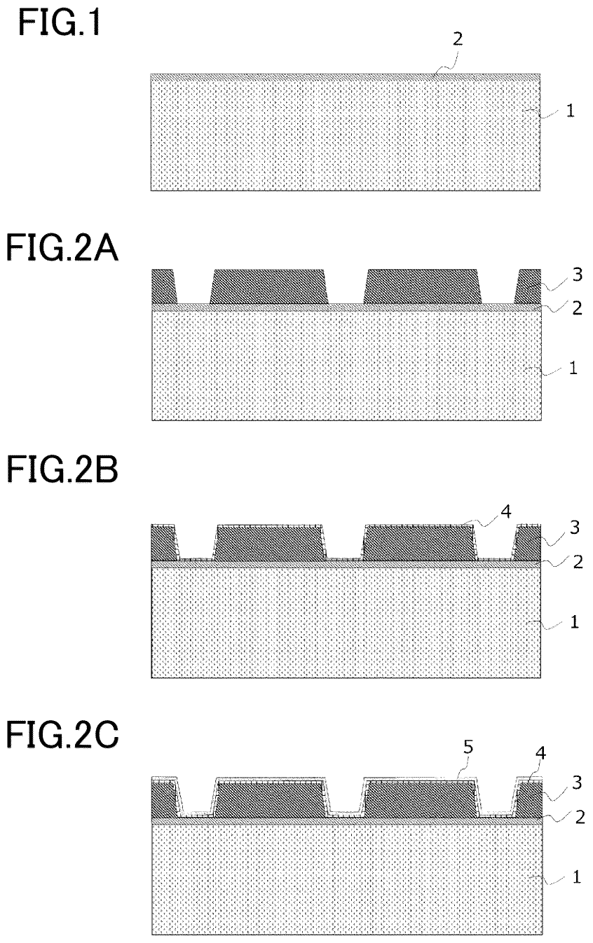

An example of a process for manufacturing a wiring board unit according to an embodiment of the present invention will be described below with reference to FIGS. 1 to 6.

First, as shown in FIG. 1, a release layer 2 required to remove the support 1 later is formed on one surface of the support 1.

The release layer 2 may be, for example, a resin that becomes peelable by applying heat or changing a property when the resin absorbs light such as UV light, or a resin that becomes peelable by foaming when heat is applied. When using a resin that becomes peelable by light such as UV light, for example laser light, the support 1 is irradiated with light from the side opposite to the side on which the release layer 2 is provided to remove the support 1 from the bonded assembly of the multilayer wiring 11 on the support and the FC-BGA substrate 12. The release layer 2 can be selected from layers made of organic resins such as epoxy resin, polyimide resin, polyurethane resin, silicone resin, polyester resin, oxetane resin, maleimide resin, and acrylic resin, and inorganic layers made of amorphous silicon, gallium nitride, metal oxide, and the like. The release layer 2 may further contain a photodegradation promoter or a light absorber, a sensitizer, or an additive such as a filler. The release layer 2 may include a plurality of layers. For example, to protect the multilayer wiring layer formed on the support 1, a protective layer may be further provided on the release layer 2, or a layer for improving the adhesion with the support 1 may be provided under the release layer 2. It is also possible to provide a laser light reflection layer or a metal layer between the release layer 2 and the multilayer wiring layer, and the configuration is not limited to the present embodiment.

Since there are cases where the release layer 2 is irradiated with light through the support 1, the support 1 preferably has transparency. For example, glass can be used. Since glass has good flatness and high rigidity, it is suitable for forming the fine pattern of the multilayer wiring 11 on the support. Further, since glass has a low coefficient of thermal expansion (CTE) and thus is less likely to distort, it is preferable in ensuring pattern placement accuracy and flatness. When glass is used as the support 1, the thickness of the glass is preferably thick to prevent it from warping during the manufacturing process. For example, the glass has a thickness of 0.7 mm or greater, preferably 1.1 mm or greater. The glass preferably has a CTE of 3 ppm/K or higher and 15 ppm/K or lower, more preferably about 9 ppm/K considering the CTEs of the FC-BGA substrate 12 and the semiconductor elements 14. Examples of the glass include quartz glass, borosilicate glass, non-alkali glass, soda glass, and sapphire glass. On the other hand, when the support 1 is not required to transmit light to remove the support 1, such as when a resin that undergoes foam when heated is used for the release layer 2, a material of the support 1 may be metal, ceramic, or another material that distorts less. In one embodiment of the present invention, the release layer 2 is made of a resin that becomes peelable by absorbing UV light, and the support 1 is made of glass.

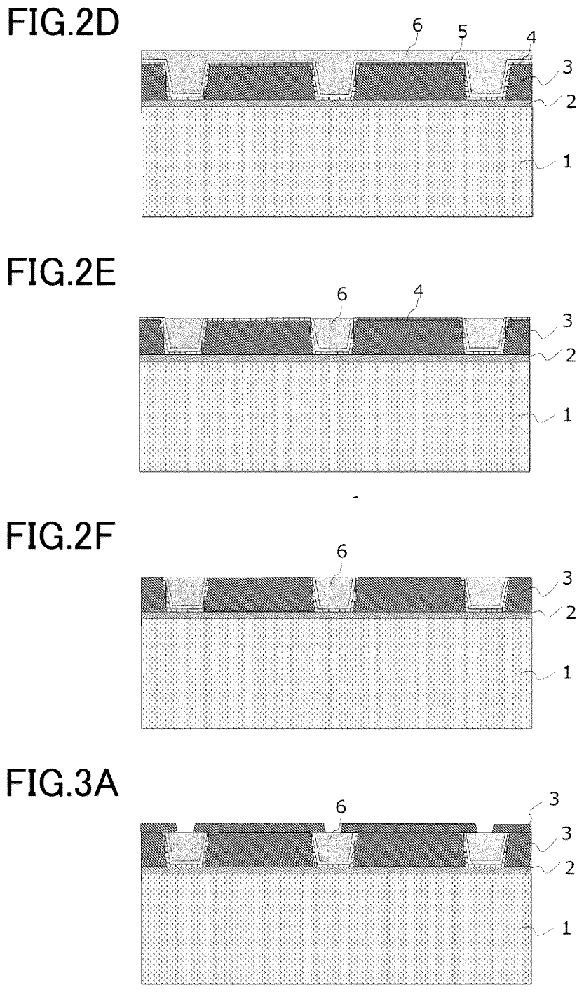

Next, as shown in FIG. 2A, a photosensitive resin layer 3 is formed. In this embodiment, the photosensitive resin layer 3 is formed by, for example, applying a photosensitive epoxy resin by spin coating. Since photosensitive epoxy resins can be cured at relatively low temperatures and shrink less due to curing after formation, they are preferable for fine pattern formation thereafter. When a liquid photosensitive resin is used, the method of forming the photosensitive resin may be selected from slit coating, curtain coating, die coating, spray coating, electrostatic coating, inkjet coating, gravure coating, screen printing, gravure offset printing, spin coating, and doctor coating. When a film-like photosensitive resin is used, lamination, vacuum lamination, or vacuum pressing may be employed. The photosensitive resin layer 3 may also be formed using, as an insulating resin, for example, a photosensitive polyimide resin, a photosensitive benzocyclobutene resin, a photosensitive epoxy resin, or a derivative thereof. Next, openings are provided in the photosensitive resin layer 3 by photolithography. The openings may be subjected to plasma treatment for the purpose of removing residues produced during development. The thickness of the photosensitive resin layer 3 is determined according to the thickness of the conductor layer portions formed in the openings, and is determined to be 7 μm, for example, in the current embodiment of the present invention. The shape of the openings in plan view is determined according to the pitch and shape of the junction electrodes of the semiconductor elements. For example, in an embodiment of the present invention, the openings with a diameter of 35 μm are formed, and the pitches are 75 μm.

Next, as shown in FIGS. 2B and 2C, a seed adhesion layer 4 and a seed layer 5 are formed in a vacuum. The seed adhesion layer 4 is a layer that improves the adhesion of the seed layer 5 to the photosensitive resin layer 3, and is a layer that prevents the seed layer 5 from peeling off. The seed layer 5 functions as a power supply layer for electroplating in wiring formation. The seed adhesion layer 4 and the seed layer 5 may be formed by, for example, sputtering or vapor deposition from one or a combination of two or more of, for example, Cu, Ni, Al, Ti, Cr, Mo, W, Ta, Au, Ir, Ru, Pd, Pt, AlSi, AlSiCu, AlCu, NiFe, ITO, IZO, AZO, ZnO, PZT, TiN, Cu3N4, and a Cu alloy. In the present invention, first, a titanium layer is formed by sputtering as the seed adhesion layer 4, and then a copper layer is formed by sputtering as the seed layer 5 considering electrical characteristics, ease of manufacturing, and cost. The total thickness of the titanium and copper layers is preferably 1 μm or less as a power supply layer for electroplating. In one embodiment of the present invention, Ti: 50 nm and Cu: 300 nm are formed.

Next, as shown in FIG. 2D, a conductor layer 6 is formed using electroplating. The conductor layer 6 will be formed into electrodes for establishing a connection with the semiconductor elements 14. Nickel electroplating, copper electroplating, chromium electroplating, Pd electroplating, gold electroplating, rhodium electroplating, iridium electroplating, or the like can be used; however, from the perspective of ease, cost, and electrical conductivity, copper electroplating is preferred. The thickness of the copper electroplating is preferred to be 1 μm or more from the perspective of serving as electrodes for connection with the semiconductor elements 14 and solder bonding and is preferred to be 30 μm or less from the perspective of productivity. In an embodiment of the present invention, Cu: 9 μm is formed in the openings of the photosensitive resin layer 3, and Cu: 2 μm is formed on the photosensitive resin layer 3.

Next, as shown in FIG. 2E, the copper layer is polished using chemical mechanical polishing (CMP) processing or the like to remove portions of the conductor layer 6 and seed layer 5. The polishing processing can be performed so that the seed adhesion layer 4 portions and the conductor layer 6 portions can form a surface. In an embodiment of the present invention, Cu: 2 m of the conductor layer 6 on the photosensitive resin layer 3 and Cu: 300 nm of the seed layer 5 are polished away.

Next, as shown in FIG. 15G, portions of the seed adhesion layer 4 and photosensitive resin layer 3 are removed using polishing such as CMP processing again. Since the polishing is performed for the different materials of the seed adhesion layer 4 and the photosensitive resin layer 3, chemical polishing is less effective but physical polishing using an abrasive is the predominant. A method similar to the polishing method described above (FIG. 2E) may be used to simplify the workflow, or the polishing method may be changed depending on the material types of the seed adhesion layer 4 and the photosensitive resin layer 3 in order to improve polishing efficiency. The conduction layer 6 remaining after the polishing serves as electrodes for bonding to the FC-BGA substrate 12.

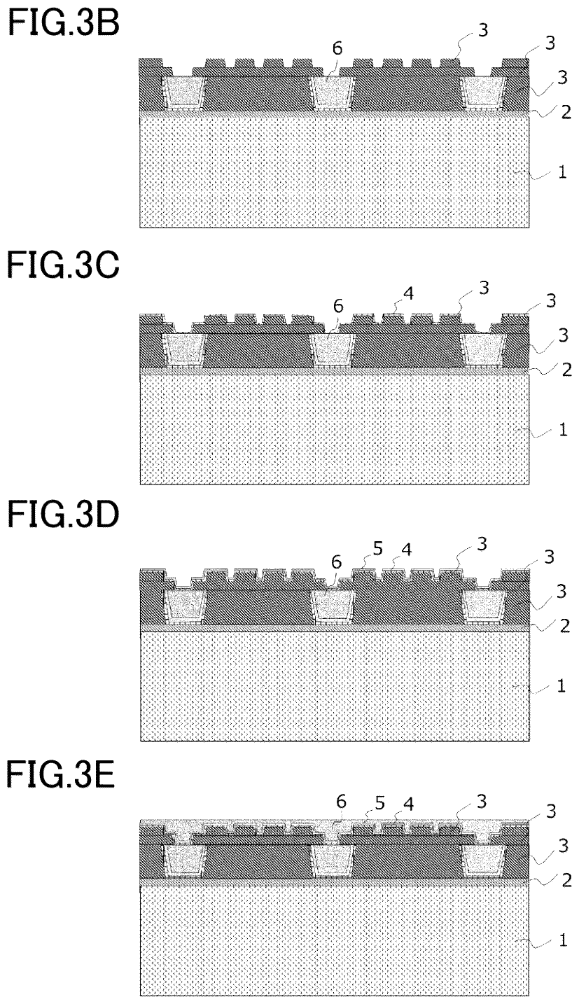

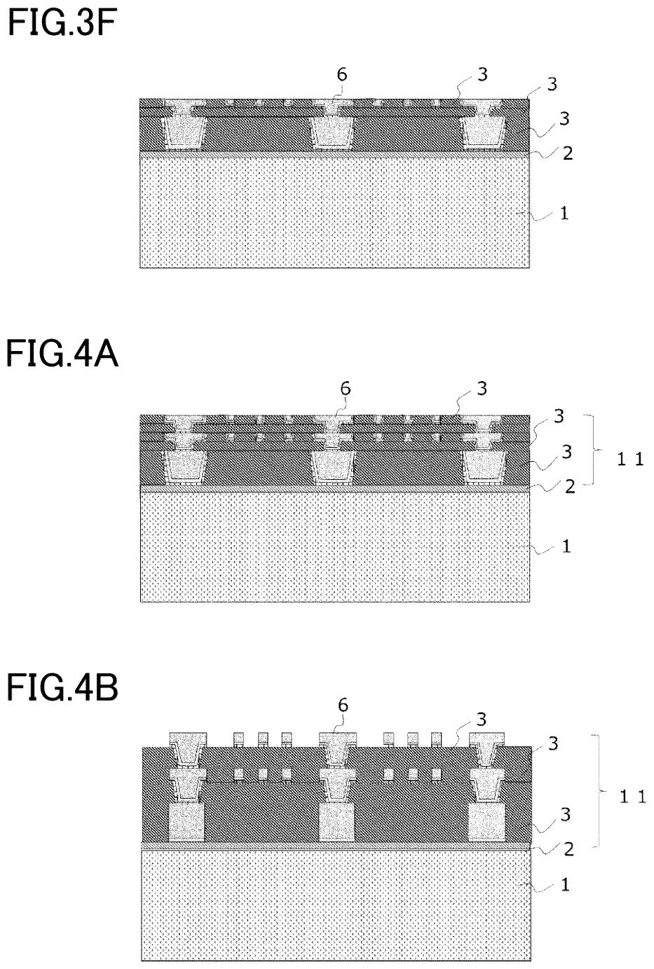

Next, as shown in FIG. 3A, a photosensitive resin layer 3 is formed on the upper surface as in FIG. 2A. The thickness of the photosensitive resin layer 3 is set according to the thickness of the conduction layer formed in the opening. The opening shape in plan view is set considering the connection with the conduction layer 6. For example, in an embodiment of the present invention, the opening shape has a diameter of 20 μm. This opening has the shape of a via that connects the upper and lower layers of the multilayer wiring.

As shown in FIG. 3B, further, a photosensitive resin layer 3 is formed on the upper surface as in FIG. 2A. The thickness of the photosensitive resin layer 3 is determined according to the thickness of the conductor layer portions formed in the openings, and is determined to be 2 μm, for example, in the current embodiment of the present invention. The shape of the openings in plan view is determined from the perspective of connectivity to a laminate. Thus, the openings are formed enclosing the outer side of the respective openings of the underlayer. In an embodiment of the present invention, openings with a diameter of φ50 μm, for example, are formed. These openings each have a shape of part of a via connecting the wiring section of the multilayer wiring with the overlayer and the underlayer.

Next, as shown in FIGS. 3C and 3D, a seed adhesion layer 4 and a seed layer 5 are formed in a vacuum as in FIGS. 2B and 2C. In one embodiment of the present invention, Ti: 50 nm and Cu: 300 nm are formed.

Next, as shown in FIG. 3E, the conduction layer 6 is formed by electroplating. The conductor layer 6 serves as vias and a wiring section. Nickel electroplating, copper electroplating, chromium electroplating, Pd electroplating, gold electroplating, rhodium electroplating, iridium electroplating, or the like can be used; however, from the perspective of ease, cost, and electrical conductivity, copper electroplating is preferred. The thickness of copper electroplating is preferred to be 0.5 μm or more from the perspective of electrical resistance of the wiring section, and is preferred to be 30 μm or less from the perspective of productivity. n an embodiment of the present invention, Cu: 6 μm is formed in the double-openings of the photosensitive resin layer 3, Cu: 4 μm is formed in the single-openings of the photosensitive resin layer 3, and Cu: 2 μm is formed on the photosensitive resin layer 3 portions.

Next, as shown in FIG. 3F, chemical mechanical polishing (CMP) processing or the like is performed to remove portions of the conductor layer 6 and seed layer 5. Subsequently, portions of the seed adhesion layer 4 and photosensitive resin layer 3 are removed using polishing such as CMP processing again. Thus, the conductor layer 6 portions remaining after the CMP processing or the like serve as conductors for the vias and the wiring section. In an embodiment of the present invention, Cu: 2 μm of the conductor layer 6 on the photosensitive resin layer 3 and Cu: 300 nm of the seed layer 5 are polished away.

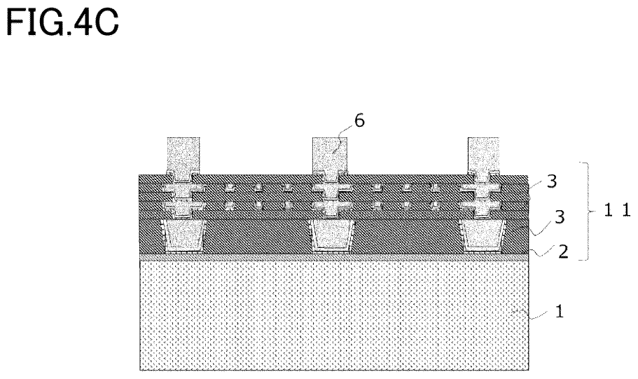

As shown in FIG. 4A, multilayer wiring 11 is formed repeating the processes shown in FIGS. 3A to 3F. In an embodiment of the present invention, two wiring layers are formed. Note that although the multilayer wiring in FIGS. 3 to 4A is formed using a damascene process, the present invention is not limited thereto, and as shown in FIG. 4B, the multilayer wiring 11 may be formed using SAP.

As shown in FIG. 4C, a conduction layer 6 serving as Cu pillars including electrodes for bonding to the semiconductor elements 14 is formed.

Next, as shown in FIG. 5A, the semiconductor elements 14 are bonded to the surface of the multilayer wiring 11 on the support 1 on the side opposite to the support via the Cu pillars and soldering (the bonding parts 21 between the semiconductor elements and the multilayer wiring).

Then, as shown in FIG. 5B, underfill 22 is filled in the vicinity of the bonding parts 21 between the semiconductor elements and the multilayer wiring so as to fix the semiconductor elements 14 to the multilayer wiring 11 on the support and seal the bonding parts.

After that, as shown in FIG. 5C, a sealing resin 20 for sealing the devices 14 is formed. The sealing resin 20 is formed by compression molding, transfer molding, or the like using a material different from that of the underfill 22, for example, one of an epoxy resin, silicone resin, acrylic resin, urethane resin, polyester resin, oxetane resin or a mixture of two or more thereof with a filler such as silica, titanium oxide, aluminum oxide, magnesium oxide, zinc oxide or the like added thereto.

Next, as shown in FIG. 5D, the release layer 2 is irradiated with laser light 13 to peel off the multilayer wiring 11 on the support on which the semiconductor element is mounted from the support 1. The support 1 can be removed by irradiating the release layer 2 formed between the support 1 and the FC-BGA substrate 12 with the laser light 13 from the back side of the support 1, that is, from the surface of the support 1 on the side opposite to the FC-BGA substrate 12 in order to make it peelable. As shown in FIG. 5E, after removing the support 1, the release layer 2 and the seed adhesion layer 4, and the seed layer 5 are removed.

Next, as shown in FIG. 5F, the multilayer wiring 11 on the support mounted with the semiconductor elements and peeled off from the support 1 is bonded (bonding parts 23 between the multilayer wiring and the FC-BGA substrate) to the FC-BGA substrate 12 by soldering to obtain the wiring board unit 15.

### <Second Method of Manufacturing First Embodiment>

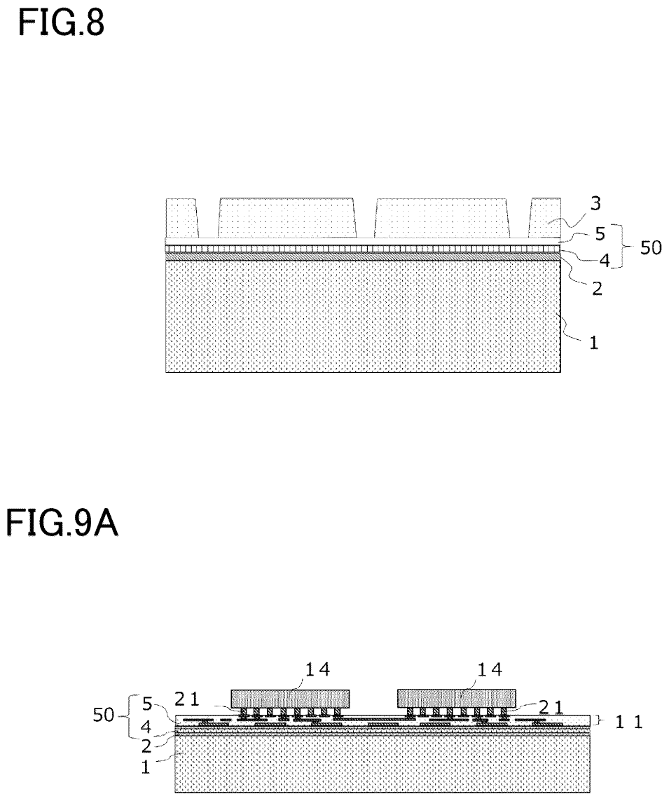

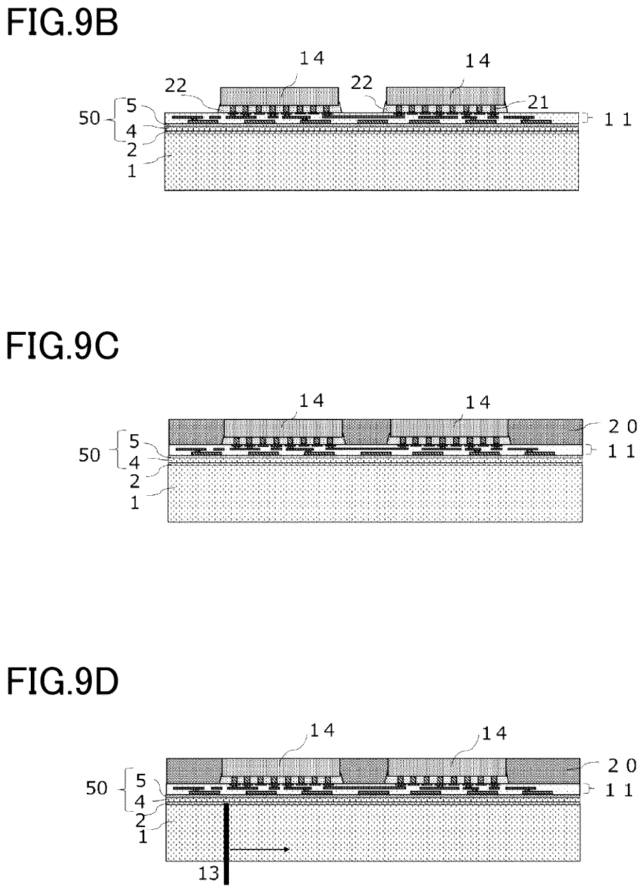

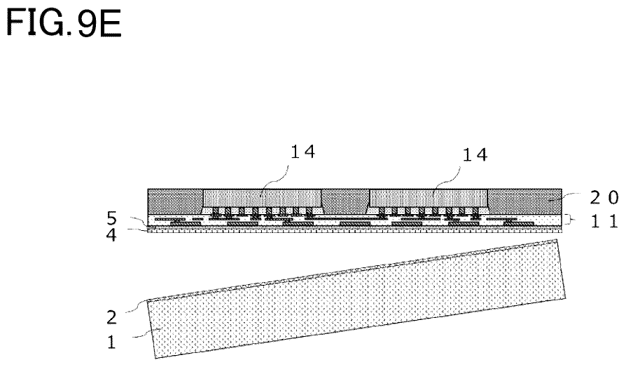

A second manufacturing method, which is a modification of the first method of manufacturing the first embodiment, will be described with reference to FIGS. 8 and 9A to 9D.

The second manufacturing method differs from the first manufacturing method in that an intermediate layer 50 is provided between the release layer 2 and the photosensitive resin layer 3. In the following description, components that are identical with or similar to components of the first manufacturing method described above are given the same or similar reference signs, and the description thereof will be simplified or omitted.

In the second manufacturing method, as shown in FIG. 8, after forming the release layer 2 needed to peel off the support 1 in a later step on one surface of the support 1, the seed adhesion layer 4 and seed layer 5 are formed as the intermediate layer 50.

The specific methods and materials for forming the seed adhesion layer 4 and the seed layer 5 may be those described with reference to FIGS. 2B and 2C.

Such an intermediate layer 50 makes it possible to improve the adhesion between the release layer 2 and the photosensitive resin layer 3 to be formed later.

Since the steps of the first manufacturing method shown in FIGS. 2B to 4C are the same in the second manufacturing method, the description thereof will be omitted.

Next, the steps of the first manufacturing method shown in FIGS. 5A to 5E correspond to FIGS. 9A to 9E. Since the intermediate layer 50 is provided in the second manufacturing method, it is possible to prevent the support 1 from peeling off before the support 1 is removed. Further, intermixing between the release layer 2 and the photosensitive resin layer 3 can be prevented.

As shown in FIG. 9E, after removing the support 1, the intermediate layer 50 formed of the seed adhesion layer 4 and seed layer 5 can be etched and removed.

### Second Embodiment

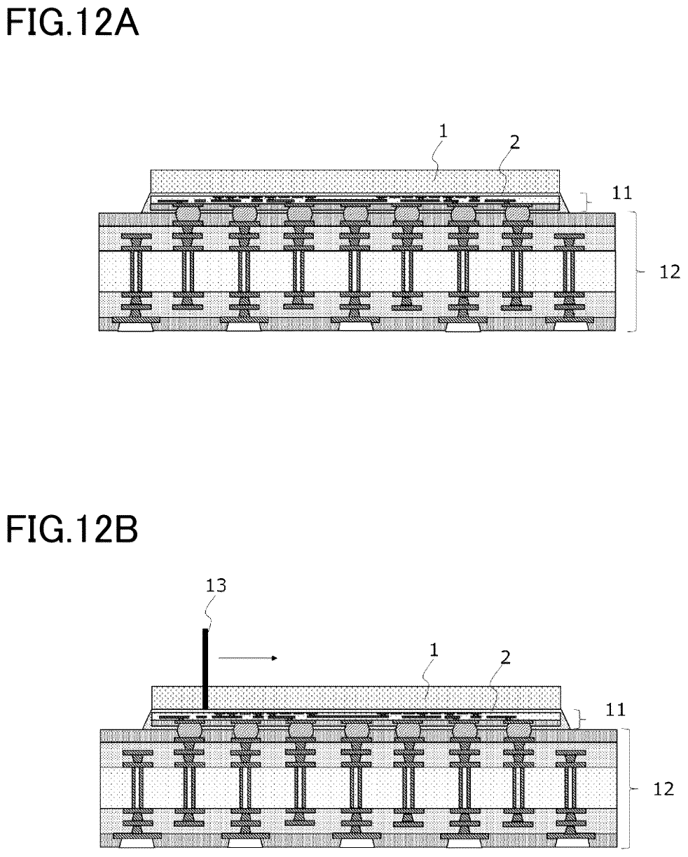

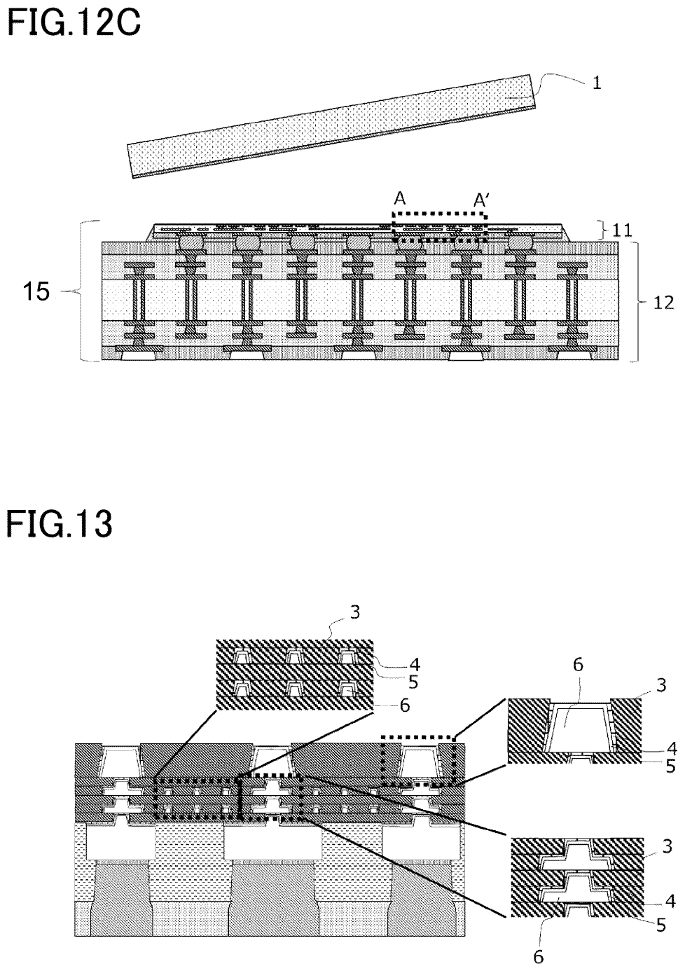

The second embodiment of the present disclosure will be described with reference to FIG. 12C.

FIG. 12C is a cross-sectional view of the wiring board unit 15 in which the multilayer wiring 11 and the FC-BGA substrate 12 are bonded.

The wiring board unit 15 includes a first wiring board including the FC-BGA substrate 12 and a second wiring board including the multilayer wiring 11 and manufactured separately from the first wiring board. The semiconductor elements 14 can be fixed to one surface (hereinafter referred to as “first surface”) of the second wiring board. The second wiring board is fixed to the first wiring board.

The inventors predicted that, also with the wiring board unit of the second embodiment, the peeling of the fine wiring layer and cracking from the location that has peeled off or a location where stress is concentrated are linked with the relative relationship between the width of the Cu pattern formed on the first surface, which is the uppermost layer of the second wiring board, and the tensile strength of the insulating resin material of the second wiring board, and studied this relationship.

The contents will be explained below with reference to FIG. 13, Tables 3 and 4, Formula 2, and the like.

FIG. 13 is an enlarged detailed cross-sectional view of an enclosed region A-A′ in FIG. 12C. In FIG. 13, five kinds of wiring board units 15 in which the uppermost conduction layers 6 have Cu patterns with different widths, i.e., 20, 50, 100, 1000, and 2000 μm were prepared. In addition, five kinds of resins having different tensile strengths, i.e., 90, 135, 145, and 170 (two kinds) MPa were used. Two kinds of resins having a tensile strength of 170 MPa but whose other physical properties differ were used to observe the influence of physical properties other than tensile strength.

A temperature cycle test was conducted on the samples thus prepared under the same conditions as those described in the first embodiment to see if cracks are formed.

The number of evaluations was N=4. Table 3 shows the results.

TABLE 3

| | |
|---|---|
| (Resin type) | Probability of cracking % |

| | | | | | | |
|---|---|---|---|---|---|---|
| Tensile | 170 | (A) | 0 | 0 | 0 | 0 |
| strength | 170 | (B) | 0 | 0 | 0 | 0 |
| MPa | 145 | (C) | 0 | 0 | 0 | 25 |
| | 135 | (D) | 0 | 0 | 25 | 50 |
| | 90 | (E) | 0 | 25 | 100 | 100 |

| | | | | |
|---|---|---|---|---|
| TST 1000 Cy | 20 | 100 | 1000 | 2000 |

Cu width μm

In order to determine the occurrence of cracking, nominal logistic regression was performed using the results shown in Table 3 to estimate a binary value indicating if cracking would occur or not, thereby obtaining the following Formula 2.

$$\begin{matrix}[ Formula 2 ] & \\ \begin{matrix}1 / ( 1 + Exp ( - A ) ) \\ A = 0.227 - 0.1619 \times Tensile strength + 6.648 \times log ( Cu pattern width )\end{matrix} & ( 2 )\end{matrix}$$

Table 4 shows the values of Formula 2 calculated using the tensile strength of the resin of the fine wiring layer and the Cu pattern width of each substrate.

TABLE 4

| | (Resin type) | Result of Formula 1 | | | |
|---|---|---|---|---|---|
| Tensile | 170 | 8E−09 | 8E−07 | 0.0006 | 0.0047 |
| strength | 170 | 8E−09 | 8E−07 | 0.0006 | 0.0047 |
| MPa | 145 | 5E−07 | 5E−05 | 0.0353 | 0.2129 |
| | 135 | 2E−06 | 0.0002 | 0.1558 | 0.5772 |
| | 90 | 0.0033 | 0.2588 | 0.9963 | 0.9995 |

| | | | | |
|---|---|---|---|---|
| TST 1000 Cy | 20 | 100 | 1000 | 2000 |

Cu width μm

In Table 4 above, for example, “8E-09” and the like represent exponential notation and means “8×10⁻⁹”.

The values in Table 4 obtained from Formula 2 are expressed in the range of 0 to 1, with 0 indicating that cracking does not occur and 1 indicating that cracking occurs. That is, a value in Table 4 can be replaced with the probability of cracking by multiplying the value by 100.

According to Tables 3 and 4, no cracks were observed after 1000 TST cycles in the substrates with a tensile strength and a Cu pattern width that give a value of 0.15 or smaller in Table 4. As for substrates with a tensile strength and a Cu pattern width that give a value of 0.15 or greater when substituted in Formula 2, in more than half of the substrates, resin cracking occurred in the fine wiring layer after 1000 TST cycles. This indicates that the probability of cracking obtained from Formula 2 is appropriate.

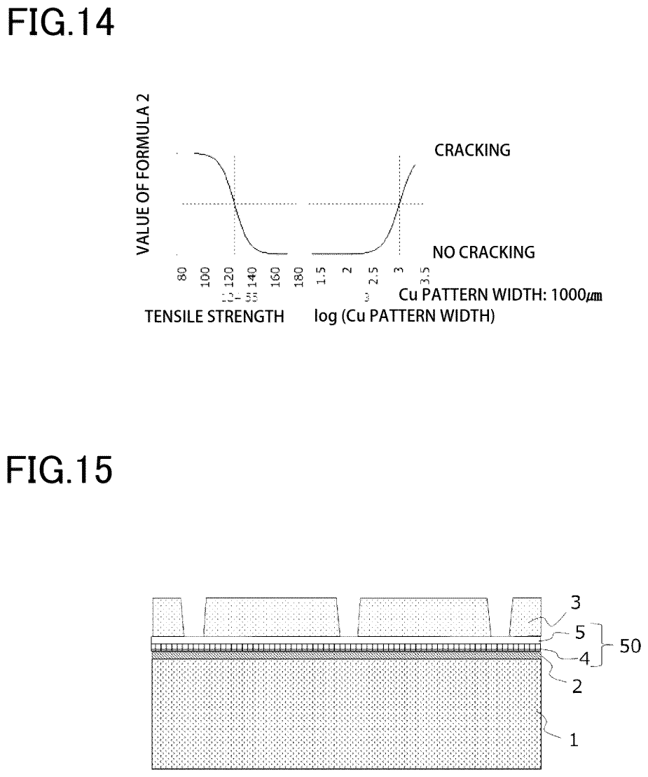

FIG. 14 shows a graph of Formula 2. In FIG. 14, the lateral broken line indicates the position where the value of Formula 2 is 0.5. In other words, this indicates the critical point between when cracking occurs and when cracking does not occur. By finding the intersection of the conditions that give a value of 0.5 when substituted in Formula 2 and the graph of Formula 2, a Cu pattern width of 1000 μm and a resin tensile strength of 124.55 can be obtained. This means that when the Cu pattern width is 1000 μm, it is necessary to use a resin with a tensile strength of 124.55 MPa or higher.

Therefore, it can be seen that the probability of cracking in the resin of the fine wiring layer has a critical point at the point where the value of Formula 2 is 0.5, and selecting a resin with a tensile strength according to the design value of the Cu pattern width is effective in ensuring that the resin in the fine wiring layer is resistant to cracking.

Further, the probability of cracking or the like is preferably less than 0.5, and preferably 0.1 or less. In this case, the required conditions for the wiring board unit can be determined by finding the relationship between the resin tensile strength and the Cu pattern width that give a value of 0.1 or smaller when substituted in Formula 2.

### <First Method of Manufacturing Second Embodiment>

An example of a process for manufacturing a wiring board unit according to an embodiment of the present invention will be described below with reference to FIGS. 1 to 4B and 10 to 12C.

However, since the steps in FIGS. 1 to 4B are the same as those in the first manufacturing method of the first embodiment, the description thereof will be omitted.

“The conduction layer 6 . . . for bonding to the FC-BGA substrate 12” in the description of FIG. 2F in the first manufacturing method of the first embodiment should be replaced with “the conduction layer 6 . . . for bonding to the semiconductor elements”.

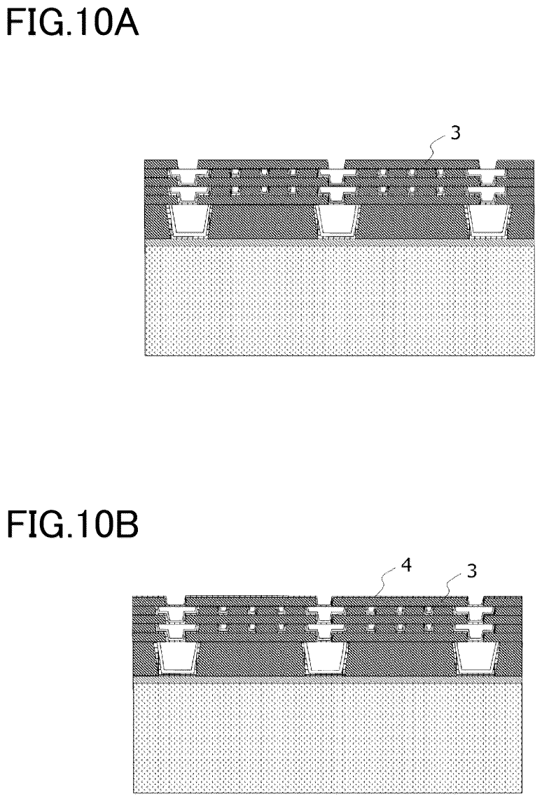

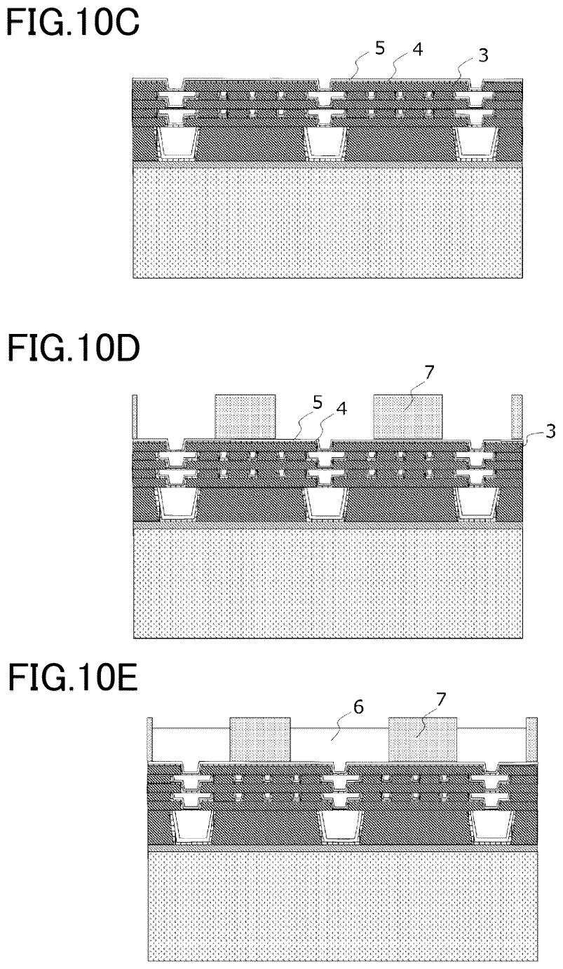

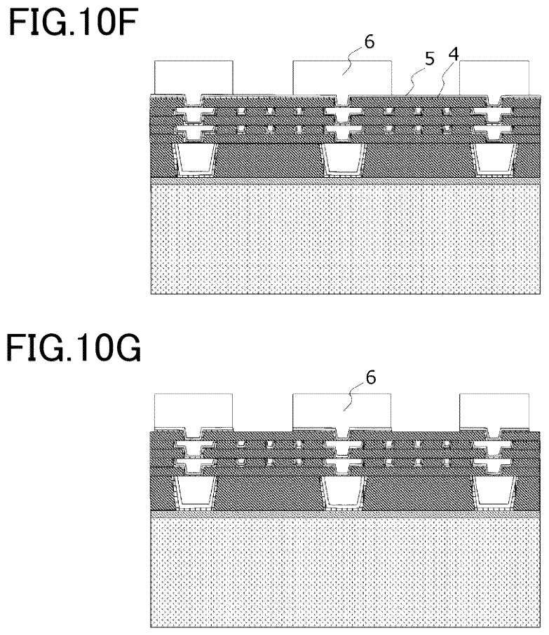

The process of forming junction electrodes with the FC-BGA substrate 12 after the multilayer wiring shown in FIG. 4A or 4B is formed will be described. As shown in FIG. 10A, a photosensitive resin layer 3 is formed on the upper surface as in FIG. 2A.

Next, as shown in FIGS. 10B and 10C, a seed adhesion layer 4 and a seed layer 5 are formed in a vacuum as in FIGS. 2B and 2C.

Then, as shown in FIG. 10D, a photoresist pattern 7 is formed. Subsequently, as shown in FIG. 10E, the conduction layer 6 is formed by electroplating. The conduction layer 6 forms electrodes for bonding to the FC-BGA substrate 12. For better solder bonding, the copper electroplating preferably has a thickness of 1 μm or greater, and for better productivity, preferably has a thickness of 30 μm or smaller. In one embodiment of the present invention, Cu: 9 μm is formed in the opening of the photosensitive resin layer 3, and Cu: 7 μm is formed over the photosensitive resin layer 3.

After that, as shown in FIG. 10F, the resist pattern 7 is removed. Then, as shown in FIG. 10G, the unnecessary seed adhesion layer 4 and seed layer 5 are etched and removed. The conduction layer 6 remaining after this serves as electrodes for bonding to the FC-BGA substrate 12.

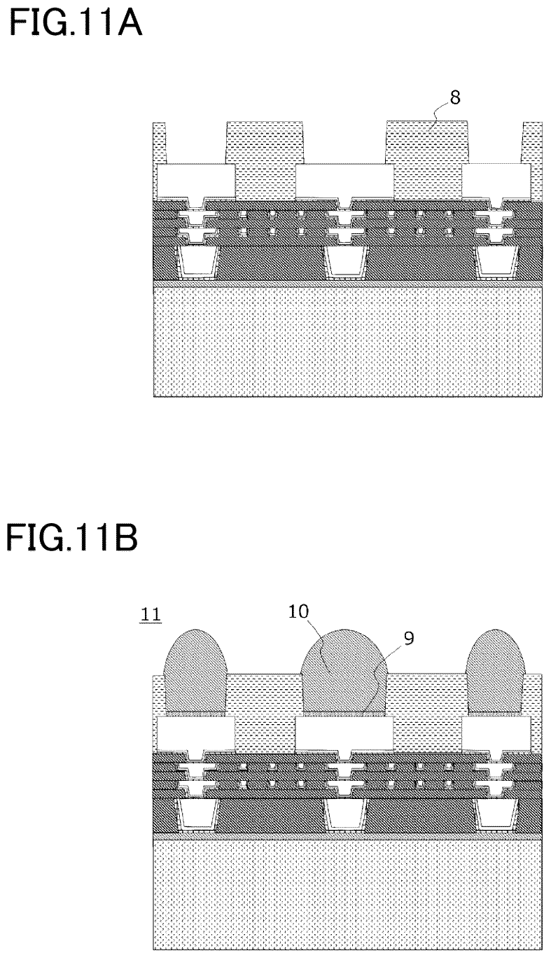

Then, as shown in FIG. 11A, a solder resist layer 8 is formed. The solder resist layer 8 is formed so that it covers the photosensitive resin layer 3 and is provided with openings that expose the conduction layer 6 after being exposed and developed. The solder resist layer 8 may be made of, for example, insulating resin such as epoxy resin or acrylic resin. In an embodiment of the present invention, the solder resist layer 8 is formed using a photosensitive epoxy resin containing filler.

Next, as shown in FIG. 11B, a surface-treatment layer 9 is provided to prevent oxidation of the surface of the conduction layer 6 and improve wettability of the solder bumps. In an embodiment of the present invention, electroless Ni/Pd/Au plating is formed as the surface-treatment layer 9. An organic solderability preservative (OSP) film (a surface-treatment film obtained using OSP water-soluble preflux) film may be formed on the surface-treatment layer 9. It is also possible to select from electroless tin plating, electroless Ni/Au plating, and the like depending on the application. Next, after mounting a solder material on the surface-treatment layer 9, the solder material is once melted and cooled to be fixed, thereby obtaining solder 10 bonding parts. The multilayer wiring 11 on the support formed on the support 1 is thus completed.

Next, as shown in FIG. 12A, after bonding the support 1 and the multilayer wiring 11 to the FC-BGA substrate 12, the bonding parts are sealed with an underfill layer. The underfill layer is made of a material, for example, one of an epoxy resin, urethane resin, silicone resin, polyester resin, oxetane resin, maleimide resin or a mixture of two or more thereof with a filler such as silica, titanium oxide, aluminum oxide, magnesium oxide, zinc oxide or the like added thereto. The underfill layer is formed by filling liquid resin.

Then, as shown in FIG. 12B, the support 1 is removed. The release layer 2 is brought into a peelable state by being irradiating with the laser light 13. The support 1 can be removed by irradiating the release layer 2 formed between the support 1 and the FC-BGA substrate 12 with the laser light 13 from the back side of the support 1, that is, from the surface of the support 1 on the side opposite to the FC-BGA substrate 12 in order to make it peelable. As shown in FIG. 12C, after removing the support 1, the release layer 2 and the seed adhesion layer 4, and the seed layer 5 are removed to obtain the wiring board unit 15.

### <Second Method of Manufacturing Second Embodiment>

A second manufacturing method, which is a modification of the first method of manufacturing the second embodiment, will be described with reference to FIG. 15.

The second manufacturing method of the second embodiment differs from the first manufacturing method in that an intermediate layer 50 is provided between the release layer 2 and the photosensitive resin layer 3. In the following description, components that are identical with or similar to components of the first manufacturing method described above are given the same or similar reference signs, and the description thereof will be simplified or omitted.

In the second manufacturing method, as shown in FIG. 15, after forming the release layer 2 needed to peel off the support 1 in a later step on one surface of the support 1, the seed adhesion layer 4 and seed layer 5 are formed as the intermediate layer 50.

The specific methods and materials for forming the seed adhesion layer 4 and the seed layer 5 may be those described with reference to FIGS. 2B and 2C.

Such an intermediate layer 50 makes it possible to improve the adhesion between the release layer 2 and the photosensitive resin layer 3 to be formed later.

After removing the support 1, the intermediate layer 50 formed of the seed adhesion layer 4 and seed layer 5 can be etched and removed.

Embodiments of the present invention have been described in the foregoing. The present invention should not be construed as limited to these embodiments, and various modifications can be made without departing from the spirit of the present invention.

Reference Signs List] 1 . . . Support; 2 . . . Release layer; 3 . . . Photosensitive resin layer; 4 . . . Seed adhesion layer; 5 . . . Seed layer; 6 . . . Conduction layer; 7 . . . Resist pattern; 8 . . . Solder resist layer; 9 . . . Surface-treatment layer; 10 . . . Solder; 11 . . . Multilayer wiring; 12 . . . FC-BGA substrate; 13 . . . Laser light; 14 . . . Semiconductor element; 15 . . . Wiring board unit; 20 . . . Sealing resin; 21 . . . Bonding part between semiconductor element and multilayer wiring; 22 . . . Underfill; 23 . . . Bonding part between multilayer wiring and FC-BGA substrate; 50 . . . Intermediate layer.

What is claimed is:

1. A wiring board unit, comprising:
a first wiring board and a second wiring board bonded to the first wiring board, a semiconductor element being resin-sealed on a surface side (hereinafter referred to as a “first surface”) of the second wiring board opposite to a surface for bonding with the first wiring board, wherein
a tensile strength of an insulating resin material used for the second wiring board and a width of a Cu pattern formed on the first surface give a value less than 0.5 when substituted in Formula 1 below.
$$\begin{matrix}[ Formula 1 ] & \\ \begin{matrix}1 / ( 1 + Exp ( - A ) ) \\ A = - 15 \text{.45} - 0.1654 \times Tensile strength + 11.31 \times log ( Cu pattern width )\end{matrix} & ( 1 )\end{matrix}$$

2. The wiring board unit of claim 1, wherein the tensile strength of the insulating resin material used for the second wiring board and the width of the Cu pattern formed on the first surface give a value of 0.1 or less when substituted in the Formula 1.

3. The wiring board unit of claim 1, where in the second wiring board is a multilayer wiring board.

4. The wiring board unit of claim 3, wherein the multilayer wiring board is formed by SAP or a damascene process.

5. The wiring board unit of claim 1, wherein the insulating resin material of the second wiring board is a photosensitive insulating resin.

6. The wiring board unit of claim 3, wherein the insulating resin material of the second wiring board is a photosensitive insulating resin.

7. The wiring board unit of claim 4, wherein the insulating resin material of the second wiring board is a photosensitive insulating resin.

8. A method of designing a wiring board unit including a first wiring board and a second wiring board bonded to the first wiring board, a semiconductor element being resin-sealed on a surface side (hereinafter referred to as a “first surface”) of the second wiring board opposite to a surface for bonding with the first wiring board,
the method including setting a tensile strength of an insulating resin material used for the second wiring board and a width of a Cu pattern formed on the first surface so that a value less than 0.5 is obtained when substituted in Formula 1 below.
$$\begin{matrix}[ Formula 1 ] & \\ \begin{matrix}1 / ( 1 + Exp ( - A ) ) \\ A = - 15 \text{.45} - 0.1654 \times Tensile strength + 11.31 \times log ( Cu pattern width )\end{matrix} & ( 1 )\end{matrix}$$

9. A wiring board unit, comprising:
a first wiring board and a second wiring board bonded to the first wiring board, a semiconductor element can be implemented on a surface side (hereinafter referred to as a “first surface”) of the second wiring board opposite to a surface bonding with the first wiring board, wherein
a tensile strength of an insulating resin material used for the second wiring board and a width of a Cu pattern formed on the first surface give a value less than 0.5 when substituted in Formula 2 below.
$$\begin{matrix}[ Formula 2 ] & \\ \begin{matrix}1 / ( 1 + Exp ( - A ) ) \\ A = 0.227 - 0.1619 \times Tensile strength + 6.648 \times log ( Cu pattern width )\end{matrix} & ( 2 )\end{matrix}$$

10. The wiring board unit of claim 9, wherein the tensile strength of the insulating resin material used for the second wiring board and the width of the Cu pattern formed on the first surface give a value of 0.1 or less when substituted in the Formula 2.

11. The wiring board unit of claim 9, wherein the second wiring board is a multilayer wiring board.

12. The wiring board unit of claim 11, wherein the multilayer wiring board is formed by SAP or a damascene process.

13. The wiring board unit of claim 9, wherein the insulating resin material of the second wiring board is a photosensitive insulating resin.

14. The wiring board unit of claim 11, wherein the insulating resin material of the second wiring board is a photosensitive insulating resin.

15. The wiring board unit of claim 12, wherein the insulating resin material of the second wiring board is a photosensitive insulating resin.

16. A method of designing a wiring board unit including a first wiring board and a second wiring board bonded to the first wiring board, a semiconductor element can be implemented on a surface side (hereinafter referred to as a “first surface”) of the second wiring board opposite to a surface for bonding with the first wiring board,
the method including setting a tensile strength of an insulating resin material used for the second wiring board and a width of a Cu pattern formed on the first surface so that a value less than 0.5 is obtained when substituted in Formula 2 below.
$$\begin{matrix}[ Formula 2 ] & \\ \begin{matrix}1 / ( 1 + Exp ( - A ) ) \\ A = 0.227 - 0.1619 \times Tensile strength + 6.648 \times log ( Cu pattern width )\end{matrix} & ( 2 )\end{matrix}$$

17. The wiring board unit of claim 2, wherein the insulating resin material of the second wiring board is a photosensitive insulating resin.

18. The wiring board unit of claim 10, wherein the insulating resin material of the second wiring board is a photosensitive insulating resin.
